(19) United States
(12) Patent Application Publication
(10) Pub. No.: US 2025/0206250 A1
(43) Pub. Date: Jun. 26, 2025

(54) Airbag Control Apparatus, Airbag System, and Vehicle

(71) Applicant: Robert Bosch GmbH, Stuttgart (DE)

(72) Inventors: Bernie Jiang, Suzhou (CN); Xinlei Zhang, Suzhou (CN)

(21) Appl. No.: 18/980,493

(22) Filed: Dec. 13, 2024

(30) Foreign Application Priority Data
Dec. 21, 2023 (CN) 2023 1177 6510.3

(51) Int. Cl. B60R 21/01; H05K 5/00

(52) U.S. Cl. CPC B60R 21/01; B60R 2021/01286; H05K 5/0026

(57) ABSTRACT

An airbag control apparatus, airbag systems, and vehicles are disclosed. The airbag control apparatus includes (i) an insulated housing including two supporting structures and two support members, (ii) two capacitors are respectively fixed in one of the two support structures, each of the two capacitors includes two leads, and the two leads of each capacitor are respectively fixed in one of the two support members, (iii) two conductive connectors, each including an integrated forming bridge and a pin, each bridge is inserted into one of the two support members, and is electrically connected with two leads fixed in a support member, and (iv) a circuit board electrically connected to the two pins of the two connectors on opposite sides of the two capacitors to the housing. By having each two leads of a total of four leads of the two capacitors share one bridge, the number of dedicated bridges is reduced by half, and the installing procedure is simplified and costs reduced.

This application claims priority under 35 U.S.C. § 119 to patent application no. CN 2023 1177 6510.3, filed on Dec. 21, 2023 in China, the disclosure of which is incorporated herein by reference in its entirety.

The present disclosure relates to the field of vehicles, and more particularly, to airbag control apparatus, airbag systems, and vehicles.

### BACKGROUND

Typically, airbags are provided in a vehicle to prevent injuries caused by collisions between occupants and internal components in a vehicle collision. The protection principle of airbags is: When the vehicle is subjected to a certain collision force, the airbag system will trigger a chemical reaction similar to the explosion of a micro-explosive. The airbags set in the vehicle will suddenly expand and eject and be in place before the occupants' body collision with parts in the vehicle. When the body comes into contact with the airbag, the airbag begins to vent through the air holes on the airbag surface, thereby reducing the impact on the body and ultimately the effect of reducing occupant injury.

As vehicles are typically damaged while airbags are operating, batteries and generators in the vehicle that power the airbag system are disconnected from the airbag system due to vehicle collisions, for which the airbag system typically also has a backup power supply to maintain power for a certain period of time. The backup power supply circuit may comprise, for example, one power control circuit and several capacitors.

### SUMMARY

Examples of the present disclosure provide for an airbag control apparatus utilizing parallel electrolytic capacitors as a backup power supply.

In a first aspect of the present disclosure, there is an airbag control apparatus comprising: The insulated housing comprises two supporting structures and two support members; the two capacitors are respectively fixed in one of the two support structures, each of the two capacitors comprises two leads, and the two leads of each capacitor are respectively fixed in one of the two support members, such that one lead from each of the two capacitors is fixed in a support member; two conductive connectors, each of the two connectors comprises an integrated forming bridge and a pin, each bridge is inserted into one of the two support members, and is electrically connected with two leads fixed in a support member; the circuit board is electrically connected to the two pins of the two connectors on opposite sides of the two capacitors to the housing.

In a second aspect of the present disclosure, an airbag system is provided. The airbag system includes an airbag control apparatus according to a first aspect of the present disclosure.

In a third aspect of the present disclosure, a vehicle is provided. The vehicle includes an airbag system according to a second aspect of the present disclosure.

It will be understood that the description in the Summary is not intended to limit key or important features of the examples of the present disclosure, nor is it intended to limit the scope of the present disclosure. Other features of the present disclosure will become readily understood by the following description.

### BRIEF DESCRIPTION OF THE DRAWINGS

Above and other features, advantages and aspects of various examples of the present disclosure will become more apparent in combination with the accompanying drawings and with reference to the following detailed description. In the figures, like or similar figures designate like or similar elements, wherein:

FIG. 1A shows a schematic view of an example vehicle, consistent with some examples of the present disclosure;

FIG. 1B shows a schematic view of an airbag control apparatus, consistent with some examples of the present disclosure;

FIG. 2A shows a schematic view of an airbag control apparatus, consistent with some examples of the present disclosure;

FIG. 2B shows a schematic view of a connector of a control apparatus according to some examples of the present disclosure; and

FIGS. 3A-3G show a schematic process for assembly of an electrolytic capacitor, consistent with some examples of the present disclosure.

### DETAILED DESCRIPTION

The examples of the present disclosure will be described in further detail below with reference to the accompanying drawings. While certain examples of the present disclosure are shown in the accompanying drawings, it should be understood that the present disclosure may be implemented in various forms and should not be construed as being limited to the examples set forth herein, rather these examples are provided for a more thorough and complete understanding of the present disclosure. It should be understood that the accompanying drawings and examples of the present disclosure are for exemplary purposes only and are not intended to limit the scope of protection of the present disclosure.

In the description of the examples of the present disclosure, the term “comprise” and other similar expressions should be understood as open-ended inclusion, that is, “comprising but not limited to”. The term “based on” should be understood as “at least partially based on”. The term “one example” or “this example” should be understood as “at least one example”. The terms “first”, “second”, etc. may refer to and represent different or the same object. The text below may comprise other specific and implicit meanings.

It will be understood that when an element is referred to as “connected” or “coupled” to another element, it may be directly connected or coupled to other elements or intermediate elements may be present, i.e., also include indirect connections or couplings. Conversely, there will be no intermediate element when the element is referred to as a “direct connection” or “direct coupling” to another element. Other words used to describe the relationship between elements should be resolved in a similar manner (e.g., “between” and “directly between”, “adjacent” and “directly adjacent”, etc.).

As discussed above, a backup power source comprising a power supply capacitor such as an electrolytic capacitor is provided in the airbag system. As the amount of energy required in the airbag system is increasing, the size of the power supply capacitor is increasing. Conventionally, the power supply capacitor is disposed in a control apparatus of the airbag system, i.e., the Electronic Control Unit (ECU). However, the size of the ECU is limited, and the size of the power supply capacitor poses a certain challenge to the design of the ECU. In some designs, the power supply capacitor is transverse in the ECU, i.e., the main axis of the columnar power supply capacitor is parallel to the circuit board, thereby reducing its size in a direction perpendicular to the circuit board.

However, since the leads of the power supply capacitor cannot be directly soldered to the circuit board, each lead needs to be connected to the circuit board using a dedicated connector. Due to the higher manufacturing costs of dedicated connectors, the overall cost of the ECU is increased and excessive resources are expended.

In view of this, a scheme of airbag control apparatus utilizing fewer numbers of connectors is presented. In this scenario, two of the four leads of the two capacitors share one connector and the other two leads share the other connector such that the two capacitors are parallel in the circuit. As a result, the number of dedicated connectors is reduced by half, simplifying the installing procedure and reducing costs.

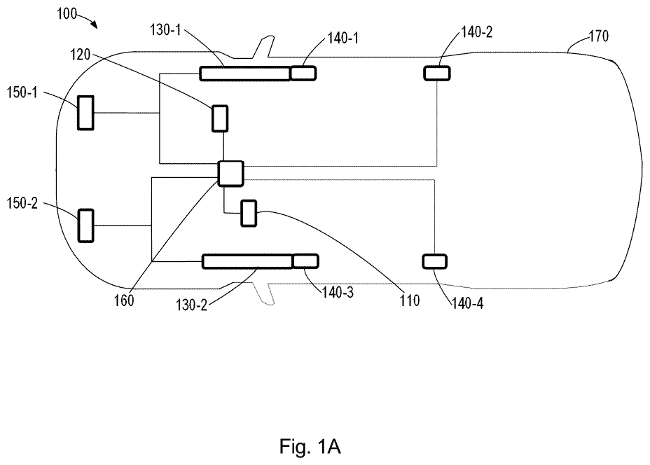

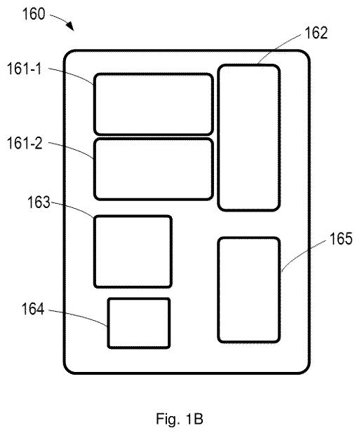

The backup power supply structure of the airbag control apparatus, consistent with examples of the present disclosure, will be described in detail below in connection with FIGS. 1-3G. FIG. 1A shows a schematic view of an example vehicle 100, consistent with some examples of the present disclosure. As shown in FIG. 1A, the vehicle 100 has a body 170. Various components of the airbag system are provided in the body 170. The airbag system consists of, for example, an ECU, a sensor, an airbag assembly, and a seat belt tensioner. When a collision occurs to the vehicle 100, the sensor detects the collision and transmits the detection signal to the ECU. The ECU then judges and controls the ignition detonator after the collision is confirmed. Since now, the nitrogen gas enters the airbags such that the airbags are fully spread between the corresponding part of the body and the occupant, thereby protecting the occupant from collision on the body.

To achieve the above functions, the airbag system may include, for example, driver airbags (DAB) 110, passenger airbags (PAB) 120 and side airbags 130-1, side airbags 130-2, side impact sensor (SIS) 140-1, side impact sensor 140-2, side impact sensor 140-3, side impact sensor 140-4, as well as front impact sensor (FIS) 150-1 and front impact sensor 150-2 for detecting collision from different directions, and airbag control apparatus ECU 160 for the control.

The front impact sensor 150-1 and the front impact sensor 150-2 (which are then referred to individually or collectively as the front impact sensor 150) are respectively disposed on both sides of the front part of body 170 to detect collisions from the left front and right front while the vehicle is traveling. Side impact sensor 140-1, side impact sensor 140-2, side impact sensor 140-3, and side impact sensor 140-4 (hereafter individually or collectively referred to as side impact sensor 140) are respectively disposed adjacent to right front door, right rear door, left front door, and left rear door. The driver airbags 110 are disposed in the steering wheel and the passenger airbags 120 are disposed in the dashboard in front of the passenger seat. The side airbags 130-1 are disposed adjacent to the side of passenger seat and the side airbags 130-2 are disposed adjacent to the side of driver seat.

The apparatus in the airbag system are coupled to the airbag control apparatus 160 and are capable of communicating with the airbag control apparatus 160. When the current impact sensor 150-1 or the front impact sensor 150-2 detects a collision from the front, the front impact sensor 150-1 or the front impact sensor 150-2 generates a detection signal and passes the detection signal to the airbag control apparatus 160. When a detection signal is received indicating a collision from the front, the airbag control apparatus 160 controls the front side driver airbags 110 or the passenger airbags 120 to eject, thereby slowing the collision to harm the occupants' head and chest. When one of the side impact sensors 140-1, 140-2, 140-3, 140-4 detects a side collision, the respective sensor will generate a detection signal and pass the detection signal to the airbag control apparatus 160. When a detection signal is received indicating a collision from the side, the airbag control apparatus 160 controls the corresponding side airbags of 130-1, 130-2 from both sides of the front seat to mitigate the chest injury from the collision if the occupant correctly uses the seat belt.

FIG. 1B shows a schematic view of an airbag control apparatus 160, consistent with some examples of the present disclosure. As shown in FIG. 1B, the airbag control apparatus 160 includes electronics arranged on a circuit board to enable control functions. A capacitor 161-1 and a capacitor 161-2, a security sensor 162, a microcontroller 163, an acceleration sensor 164, and an ignition circuit 165 may be provided on a circuit board. The capacitor 161-1 and the capacitor 161-2 store spare energy and serve as a backup power supply when the vehicle's battery is down or power fails. The security sensor 162 is configured to turn on the airbag circuit upon satisfying the airbag development condition to prevent misoperation due to impact/electromagnetic wave interference. The microcontroller 163 stores a variety of programs to control the entire airbag system. The acceleration sensor 164 is configured to detect an acceleration from the collision. The ignition circuit 165 is configured to provide ignition energy to the airbag.

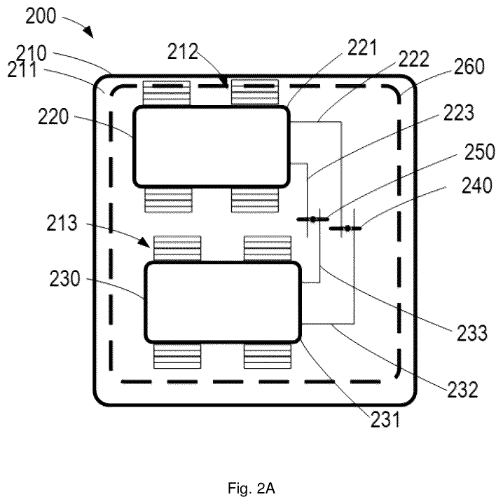

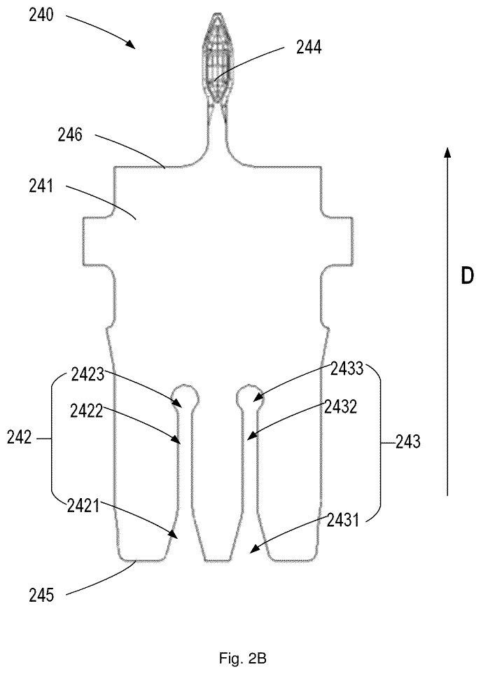

In the illustrated example, a large number of electronics are provided within the limited space of the airbag control apparatus 160 to provide corresponding functionality. Accordingly, the spare energy required is greater such that the arrangement of the electrolytic capacitors has a significant impact on the spatial design of the airbag control apparatus 160. The mounting structure for the electrolytic capacitor will be described below with reference to FIGS. 2A-2B.

FIG. 2A shows a schematic view of an airbag control apparatus 200, consistent with some examples of the present disclosure. As shown in FIG. 2A, the airbag control apparatus 200 includes a housing 210. The housing 210 may be made, for example, by an injection molding process, the housing 210 having a mounting face 211 located inside. A first support structure 212 and a second support structure 213 for securing the capacitor are provided on mounting face 211. In some examples, the first support structure 212 and second support structure 213 may include feet arranged at four corners of the rectangle for supporting and securing the capacitor.

The airbag control apparatus 200 also includes a first capacitor 220 and a second capacitor 230. The first capacitor 220 is transversely set inside the first support structure 212 and the second capacitor 230 is transversely set inside the second support structure 213. For example, the primary axises of the columnar first capacitor 220 and second capacitor 230 may be parallel to the mounting face 211. At the same time, the first support structure 212 and second support structure 213 are arranged such that the primary axises of the first capacitor 220 and second capacitor 230 are parallel to each other. It should be understood that the number of electrolytic capacitors is merely exemplary and that the airbag control apparatus 200 may also include a greater number of parallel electrolytic capacitors, which are equally applicable to connection schemes of examples of the present disclosure.

Referring to FIG. 2A, the first capacitor 220 has a columnar first columnar body 221, a first lead 222, and a second lead 223. In some examples, the first and second leads 222, 223 may have an L-shape and be parallel to one another. For example, the first and second leads 222, 223 may begin to extend outwardly from an end surface of the columnar first columnar body 221 in a direction parallel to the main axis of the first columnar body 221 and bend 90° at the turn towards the second capacitor 230, after which the extension continues towards the second capacitor 230 to form an L-shape. Accordingly, the second capacitor 230 has a columnar second columnar body 231, a third lead 232, and a fourth lead 233. In some examples, the third and fourth leads 232, 233 may have an L-shape and be parallel to one another. For example, the third and fourth leads 232, 233 may begin to extend outwardly from an end surface of the columnar second columnar body 231 in a direction parallel to the main axis of the second columnar body 231 and bend 90° at the turn towards the first capacitor 220, after which the extension continues towards the first capacitor 220 to form an L-shape. A first support member and a second support member positioned between the first and second capacitors 220, 230 are also provided on the mounting face 211 of the housing 210. The first and third leads 222, 232 are fixed in the first support member and the second and fourth leads 223, 233 are fixed in the second support member.

In some examples, the first and second capacitors 220, 230 may be the same. The first and second capacitors 220, 230 are of the same size as well as the same leads. In such examples, to cause the leads of the first and second capacitors 220, 230 to be staggered, the first and second support structures 212, 213 may be biased against one another in the direction of the primary axis of the capacitor such that the first capacitor 220 may be biased relative to the second capacitor 230 in the direction of its primary axis. In this case, although the first and second capacitors 220, 230 are set side by side, they are not aligned. In this way, using the same capacitor can reduce production difficulties. Moreover, setting the capacitor side by side allows the entire control unit to be more compact without the control unit being too long in the direction of the capacitor's primary axis.

In some examples, the length of the first lead 222 of the first capacitor 220 and the third lead 232 of the second capacitor 230 may be set such that the ends of the first and third leads 222, 232 overlap in a direction parallel to the primary axis of the second columnar body 231. The length of the second lead 223 of the first capacitor 220 and the fourth lead 233 of the second capacitor 230 may be set such that the ends of the second and fourth leads 223, 233 overlap in a direction parallel to the primary axis of the second columnar body 231.

The airbag control apparatus 200 also includes a circuit board 260. The circuit board 260 may be, for example, a printed circuit board (PCB). In some examples, the circuit board 260 may be arranged parallel to the mounting face 211 and spaced a distance from the mounting face 211 such that a first capacitor 220 and a second capacitor 230 are located between the mounting face 211 and the circuit board. Further, the circuit board 260 is coupled to the housing 210. In some examples, the circuit board 260 may be secured to the housing 210 via a threaded connection.

The airbag control apparatus 200 also includes a first connector 240 and a second connector 250. The first and second connectors 240, 250 include an integrated forming bridge and pin, respectively. A bridge of the first connector 240 is inserted into the first support member and electrically connected with the first and third leads 222, 232 fixed in the first support member. A bridge of the second connector 250 is inserted into the second support member and electrically connected with the third and fourth leads 223, 233 fixed in the second support member. Further, the pin of the first connector 240 is electrically connected with the circuit board 260, and the pin of the second connector 250 is electrically connected with the circuit board 260. As such, the first lead 222 of the first capacitor 220 and the third lead 232 of the second capacitor 230 are electrically connected to each other via the first connector 240 and electrically coupled to the circuit board 260 via pins of the first connector 240 such that the first and third leads 222, 232 are electrically coupled to the circuit board 260. Accordingly, the second lead 223 of the first capacitor 220 and the fourth lead 233 of the second capacitor 230 are electrically connected to each other via the second connector 250 and electrically connected to the circuit board 260 via the second connector 250 pin such that the second and fourth leads 223 and 233 are electrically connected to the circuit board 260.

In the example shown in FIG. 2A, the installation and manufacturing costs are reduced by the first connector shared by the first and third leads and the second connector shared by the second and fourth leads in place of the four connectors used conventionally, simplifying the parallel circuit of the circuit board. It should be understood that the first and second connectors 240, 250 in FIG. 2A may be the same, and the detailed structure of the connector 240, consistent with examples of the present disclosure, will be described in detail with reference to FIG. 2B below, for brevity purposes.

FIG. 2B shows a schematic view of a connector 240 of a control apparatus, consistent with some examples of the present disclosure. The first connector 240 includes a first bridge 241. The first bridge 241 is a sheet and extends in a first direction D perpendicular to the circuit board 260 in the assembled state of the control apparatus connector 240. For ease of discussion, the first bridge 241 will be described below with reference to the first direction D. The first bridge 241 is formed, for example, by plate stamping.

The first bridge 241 includes a first slot 242 and a second slot 243. The first and second slots 242, 243 begin to extend along the first direction D from a first end 245 of the first bridge 241 on a reverse portion of the first direction D. That is, in the assembled state, the first and second slots 242, 243 extend in a direction towards the circuit board 260 from a first end 245 of the first bridge 241 proximate the first support member. The first slot 242 is adapted to extend through the first lead 222 and the second slot 243 is adapted to extend through the third lead 232. For example, in the assembled state of the connector 240 of the control apparatus, a periphery of the first lead 222 is in contact with an inner wall of the first slot 242 and a periphery of the third lead 232 is in contact with an inner wall of the second slot 243 such that the first bridge 241 is electrically coupled with the first and third leads 222 and 232. It should be understood that the illustrated structure of the first and second slots 242, 243 is merely exemplary and that the first and second slots 242, 243 may be provided on respective positions in any suitable shape.

In the example, the first slot 242 includes three portions according to a section, a rabbet 2421 at the first end 245, a channel 2422 extending from the rabbet 2421 in the first direction D, and a slot bottom 2423 at the first direction D termination of the first slot 242. The width between the inner walls of the rabbet 2421 is getting smaller in a direction toward the circuit board 260 to facilitate passing of the first lead 222 through when assembled. The width between the rabbet 2421 and the inner wall of the channel 2422 between the slot bottom 2423 is consistent. That is, channel 2422 has a section of a rectangle. And the width between the inner walls of the slot bottom 2423 is greater than the width between the inner walls of the channel. In some examples, the section of the slot bottom 2423 may be approximately full circled, and the interior of the slot bottom is a continuous columnar surface. After assembly, the periphery of the first leads 222 may be in contact with the channel 2422. The slots with a tapering width can be provided to facilitate the connector to be attached to the lead during assembly. The requirement for assembly tolerances can be reduced by setting longer channels. Stress concentrations can be eliminated by setting a slot bottom that is wider than the channel.

Correspondingly, the second slot 243 is parallel to the first slot 242 and also includes three portions according to sectioning, namely the rabbet 2431 at the first end 245, the channel 2432 extending from the rabbet 2431 in the first direction D, and the slot bottom 2433 at the first direction D termination of the second slot 243. The width between the inner walls of the rabbet 2431 is getting smaller and smaller in the first direction D to facilitate passing of the third lead 232 through when assembled. The width between the rabbet 2431 and the inner wall of the channel 2432 between the slot bottom 2433 is consistent. That is, channel 2432 has a section of a rectangle. The width between the inner walls of the slot bottom 2433 is greater than the width between the inner walls of the channel 2432. In some examples, the section of the slot bottom 2433 may be approximately full circled, and the interior of the slot bottom is a continuous columnar surface. After assembly, the periphery of the first leads 222 may be in contact with the channel 2432.

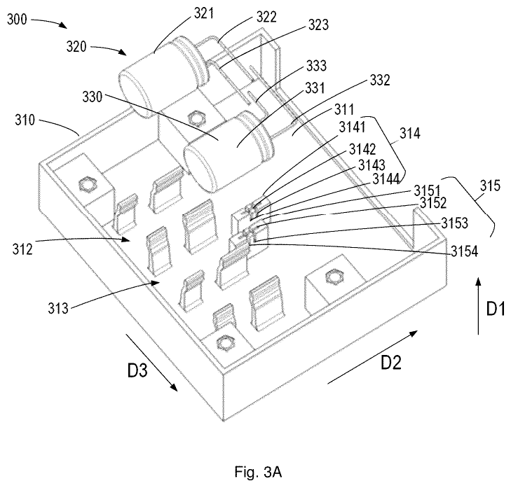

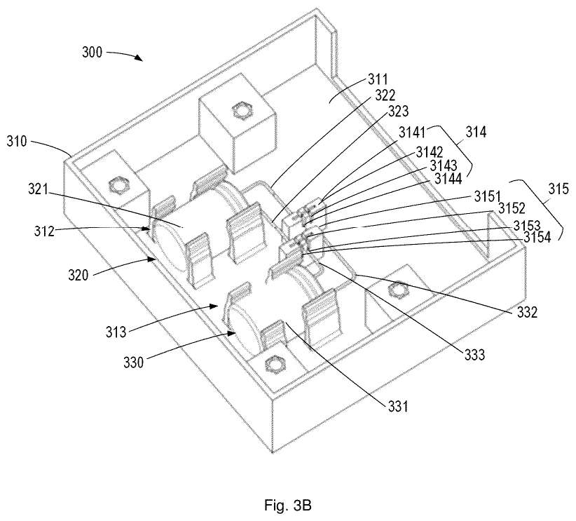

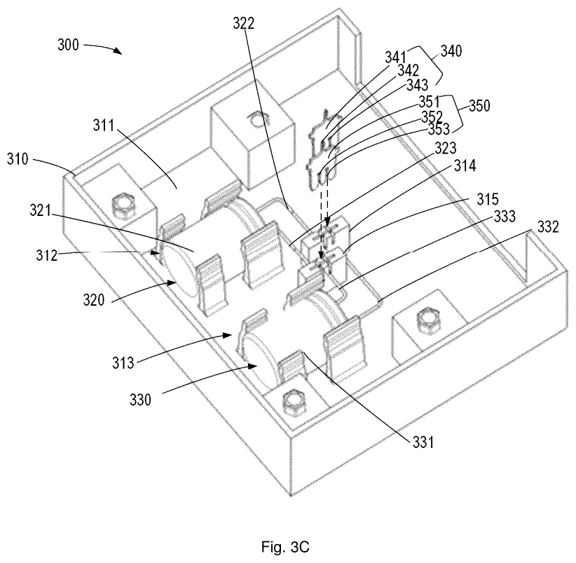

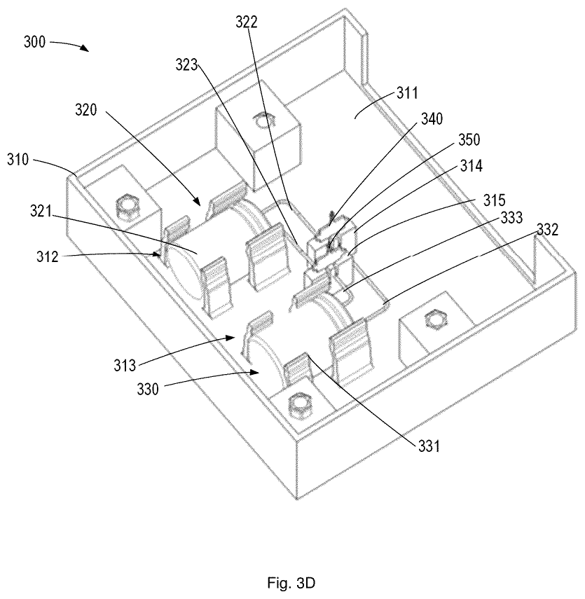

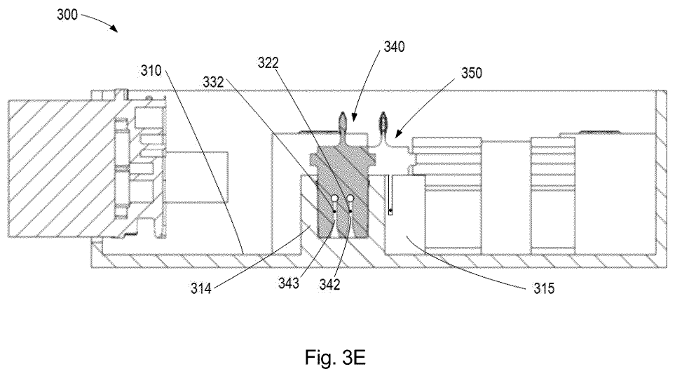

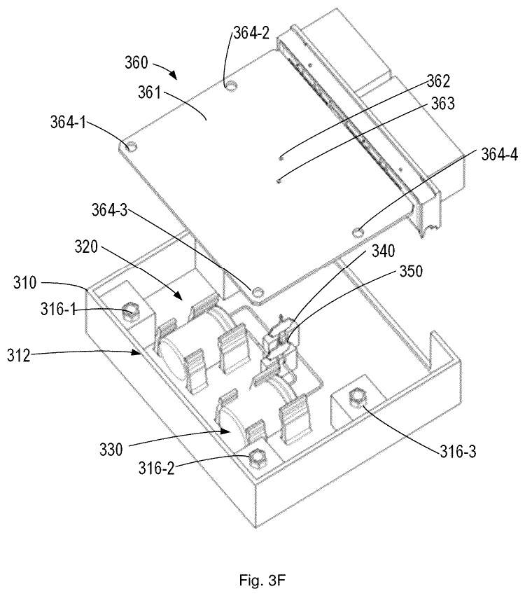

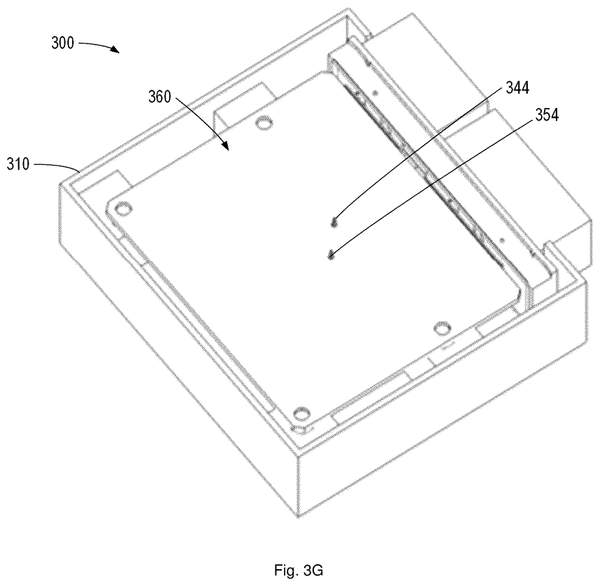

Further, the first bridge 241 has a first press-fit pin 244 at the forwardly facing second end 246 of the first direction D. The first press-fit pin 244 includes a press-fit structure such that the first press-fit pin 244 can be electrically coupled with the circuit board 260 in a press-fit manner. For example, the first press-fit pin 244 is adapted to be inserted in a corresponding metal hole of the circuit board 260. In the illustrated example, the two leads can be electrically connected without additional apparatus by providing two slots for receiving the leads. FIGS. 3A-3G below illustrate a schematic process for an assembly process of an electrolytic capacitor, consistent with some examples of the present disclosure.

In some examples, unlike the example shown in FIGS. 2A and 2B, the first and second bridges 241, 251 may each have only one slot for receiving leads. In this example, both the first lead and the third lead pass through the same slot of the first bridge and both the second lead and the fourth lead pass through the same slot of the second bridge.

FIG. 3A shows a schematic view of the electrolytic capacitor before it is installed, consistent with some examples of the present disclosure. As shown in FIG. 3A, the airbag control apparatus 300 includes a housing 310. The housing 310 has a mounting face 311 located inside. A first support structure 312 and a second support structure 313 are provided on the mounting face 311 for containing the electrolytic capacitor. The first support structure 312 and the second support structure 313 include feet arranged at four corners of the rectangle for supporting and securing the electrolytic capacitor. The first and second support structures 312, 313 are arranged such that after the electrolytic capacitor is installed in the support structure, the primary axis of the electrolytic capacitors extends along the second direction D2.

A first support member 314 and a second support member 315 are also provided on the mounting face 311. The first and second support members 314, 315 are biased in a direction perpendicular to the primary axis of the columnar body. In some alternative examples, the first and second support members 314, 315 may be relatively overlapping in a direction perpendicular to the primary axis of the columnar body.

The first support member 314 includes a first support member body 3141 extending in the first direction D1 perpendicular to the mounting face 311. A first socket 3142 is provided in the first support member body 3141. The first socket 3142 extends from an end surface of the first support body 3141 in the first direction D1 towards the mounting face 311. The first support member 314 also includes a first lead channel 3143 and a second lead channel 3144 through the first support member body 3141. The first and second lead channels 3143 and 3144 extend from the end face toward the mounting face 311 and extend from one end face of the first support member body 3141 to another end face on the third direction D3 perpendicular to the second direction D2.

The second support member 315 includes a second support member body 3151 extending in the first direction D1. A second socket 3152 is provided in the second support member body 3151. The second socket 3152 extends from an end surface of the second support member body 3151 in the first direction D1 towards the mounting face 311. The second support member 315 also includes a third lead channel 3153 and a fourth lead channel 3154 through the second support member body 3151. The third and fourth lead channels 3153 and 3154 extend from the end face toward the mounting face 311 and from one end face of the second support member body 3151 to another end face on the third direction D3.

The first support member 314 is offset relative to the second support member 315 in the third direction D3. In this manner, by staggering the first support member 314 and the second support member 315, the first support member 314 and the second support member 315 may be allowed to overlap in the second direction D2, thereby reducing the size in the second direction D2.

FIG. 3A also illustrates a first capacitor 320 and a second capacitor 330. The primary axises of the columnar first and second capacitors 320, 330 are parallel to each other and to the mounting surface 211. The first capacitor 320 has a columnar first columnar body 321, a first lead 322, and a second lead 323. The first and second leads 322, 323 have an L-shape and are parallel to each other. Specifically, the first and second leads 322, 323 begin to extend outward in the second direction D2 from the end face of the columnar first columnar body 321 and bend 90° at the turn towards the second capacitor 330 and continue to extend along the third direction D3 towards the second capacitor 230. Accordingly, the second capacitor 330 has a columnar second columnar body 331, a third lead 332, and a fourth lead 333. The third and fourth leads 332, 333 have an L-shape and are parallel to each other. Specifically, the third and fourth leads 332, 333 begin to extend outward in the second direction D2 from the end face of the columnar second columnar body 331 and bend 90° at the turn towards the first capacitor 320 and continue to extend against the third direction D3 towards the first capacitor 220. The first and second capacitors 320, 330 will be mounted to the first and second support structures 312, 313, respectively, at a current pose.

FIG. 3B shows a schematic diagram of an electrolytic capacitor being mounted to a housing, consistent with some examples of the present disclosure. During installation, the first lead 322 of the first capacitor 320 enters the second lead channel 3144 from an end face of the first support member body 3141 and the second lead 323 enters into the fourth lead channel 3154 from an end face of the second support member body 3151. Accordingly, the third lead 332 of the second capacitor 330 enters into the first lead channel 3143 from an end face of the first support member body 3141, and the fourth lead 333 enters into the third lead channel 3153 from an end face of the second support member body 3151. As shown in FIG. 3B, when the first and second capacitors 320, 330 are mounted into the housing 310, the first lead 322 of the first capacitor 320 passes through the second lead channel 3144 and through the first support member 314, and the second lead 323 passes through the fourth lead channel 3154 and through the second support member 315. The third lead 332 of the second capacitor 330 passes through the first lead channel 3143 and through the first support member 314, and the fourth lead 333 passes through the third lead channel 3153 and through the second support member 315.

FIG. 3C shows a schematic view of connectors prior to installation, consistent with some examples of the present disclosure. FIG. 3C shows the first and second connectors 340, 350. The first connector 340 includes a first bridge 341. The first bridge 341 is sheet and extends in the first direction D1. The first bridge 341 includes a first slot 342 and a second slot 343. The first and second slots 342, 343 begin to extend along the first direction D1 from a first end of the first connection 341 on a reverse of the first direction D1. The first slot 342 is adapted to extend through the first lead 322 and the second slot 343 is adapted to extend through the third lead 332.

The second connector 350 includes a second bridge 351. The second bridge 351 is sheet and extends in the first direction D1. The second bridge 351 includes a third slot 352 and a fourth slot 353. The third and fourth slots 352, 353 begin to extend along the first direction D1 from one end of the second bridge 351 on the reverse of the first direction D1. The third slot 352 is adapted to extend through the second lead 323 and the fourth slot 353 is adapted to extend through the fourth lead 333. The first connector 340 will be inserted in the first socket 3142 of the first support member 314 and the second connector 350 will be inserted in the second socket 3152 of the second support member 315.

FIG. 3D shows a schematic view of connectors mounted to a housing, consistent with some examples of the present disclosure. During installation, when the first connector 340 is inserted into the first socket 3142, the first slot 342 is aligned with the second socket 3144 and the second slot 343 is aligned with the first socket 3143 such that the first connector 340 is [text missing]. As the second connector 350 is inserted into the second socket 3152, the third slot 352 is aligned with the fourth socket 3154 and the fourth slot 344 is aligned with the third socket 3153. As shown in FIG. 3D, when the installation is complete, a periphery of the first lead 322 contacts an inner wall of the first slot 342 and a periphery of the third lead 332 contacts an inner wall of the second slot 343. At the same time, a periphery of the second lead 323 is in contact with an inner wall of the third slot 352, and a periphery of the fourth lead 333 is in contact with an inner wall of the fourth slot 353.

FIG. 3E shows a schematic cross-sectional view of a connector when mounted to a housing, consistent with some examples of the present disclosure. As shown in FIG. 3E, a first connector 340 is secured in the first support member 314. A second connector 350 is secured in the second support member 315. The first lead 322 of the first capacitor 320 is located at a channel of the first slot 342, and the third lead 332 of the second capacitor 330 is located at a channel of the second slot 343.

FIG. 3F shows a schematic view of a circuit board prior to installation, consistent with some examples of the present disclosure. As shown in FIG. 3F, the airbag control apparatus 300 also includes a circuit board 360. The circuit board 360 may be, for example, a printed circuit board. The circuit board 360 includes a substrate 361. Mounting aperture 364-1, 364-2, 364-3, 364-4 for coupling to the housing 310 is provided on the substrate 361. The housing 310 includes bolts 316-1, 316-2, 316-3, 316-4 corresponding to mounting holes 364-1, 364-2, 364-3, 364-4, respectively. In addition, holes 362 and 363 are also provided on the substrate 361 for the press-fit pins for socket of the connectors. Oppositely, the first bridge 341 has a first press-fit pin 344 and the second bridge 351 has a second press-fit pin 354.

FIG. 3G shows a schematic view of a circuit board mounted to a housing, consistent with some examples of the present disclosure. During installation, bolts 316-1, 316-2, 316-3, 316-4 pass through corresponding mounting holes 364-1, 364-2, 364-3, 364-4 and secure the substrate 361 of the circuit board 360 to the housing 310. At the same time, the holes 362 and 363 are aligned with the first press pin 344 and the second bridge 351, respectively. As shown in FIG. 3G, after the circuit board is installed, the first press-fit pin 344 is inserted through hole 362 and the second press-fit pin 354 is inserted through hole 363.

It should be understood that utilizing the electrolytic capacitor to power is merely exemplary. The power supply capacitor may also be other capacitors capable of storing energy, such as super-capacitors. The present disclosure is not intended to limit this.

While the claims in this application have been formulated with respect to particular combinations of features, it should be understood that the scope of the disclosure also includes any novel combination of any novel features or features disclosed herein expressly or implicitly, or as any generalization thereof, whether or not it relates to the same scheme in any of the claims currently claimed.

What is claimed is:

1. An airbag control apparatus, comprising:
an insulated housing that includes two support structures and two support members;
two capacitors respectively fixed in one of the two support structures, and each of the two capacitors includes two leads, wherein the two leads of each capacitor are respectively fixed at one of the two support members so that a lead from each of the two capacitors is fixed in a support member;
two electrically conductive connectors, each of which includes an integrated forming bridge and a pin, and each of which is inserted into one of the two support members and electrically connected with two leads fixed in the one support; and
a circuit board positioned on the opposite side of the two capacitors to the housing and electrically connected with the two pins of the two connectors respectively.

2. The apparatus of claim 1, wherein the bridge comprises:
two slots each extending from a first end of the bridge proximate the support member in a direction toward the circuit board, wherein two leads fixed within the support member extend through one of the two slots and into contact with an interior wall of the slot, respectively.

3. The apparatus of claim 2, wherein each of the two slots comprises:
a rabbet opened at the first end, wherein a width between the inner walls of the rabbet becomes smaller in a direction toward the circuit board;
a channel extending from the rabbet in a direction towards the circuit board and receiving a lead, wherein a width is consistent between the inner walls of the channel; and
a slot bottom proximate an end of the circuit board of the channel, wherein a width between the inner walls of the slot bottom is greater than a width between the inner walls of the channel.

4. The apparatus of claim 1, wherein:
the two capacitors are electrolytic capacitors, each of the two capacitors including a columnar body fixed in a support structure, the columnar body having a main axis parallel to the circuit board,
the housing is made by an injection molding process,
the two support structures are arranged side-by-side, and
the columnar bodies of the two capacitors are parallel to each other, and two leads of each of the two capacitors extend from the body in a direction parallel to the primary axis and bend each towards the other capacitor proximate the two capacitors to extend into one of the support member.

5. The apparatus of claim 4, wherein the two support structures are offset by a distance from each other in a direction parallel to a primary axis of the columnar body, and the two support structures are offset by a distance from each other in a direction parallel to the primary axis of the columnar body.

6. The apparatus of claim 4, wherein the two support members are biased or overlapped in a direction perpendicular to a primary axis of the columnar body.

7. The apparatus of claim 6, wherein each of the two support members comprises:
a slot and two lead channels, each of which is in a direction perpendicular to the primary axis of the columnar body through a support member and communicates with the slot, and each of which receives one lead, the connector being formed by metal plate stamping, and the bridge being inserted into the slot.

8. The apparatus of claim 1, wherein the pin comprises a press-fit structure, the pin being press-fit in electrical connection with the circuit board.

9. An airbag system comprising an airbag control apparatus according to claim 1.

10. A vehicle comprising the airbag system of claim 9.
